(19) United States
(12) Patent Application Publication
(10) Pub. No.: US 2020/0321437 A1
(43) Pub. Date: Oct. 8, 2020

(54) SILICON CARBIDE EPITAXIAL WAFER, METHOD FOR MANUFACTURING SILICON CARBIDE EPITAXIAL WAFER, AND POWER CONVERTER

(71) Applicant: Mitsubishi Electric Corporation, Tokyo (JP)

(72) Inventors: Masashi SAKAI, Tokyo (JP); Yoichiro MITANI, Tokyo (JP); Takuyo NAKAMURA, Tokyo (JP)

(73) Assignee: Mitsubishi Electric Corporation, Tokyo (JP)

(21) Appl. No.: 16/743,462

(22) Filed: Jan. 15, 2020

(30) Foreign Application Priority Data
Apr. 5, 2019 (JP) 2019-072654

(51) Int. Cl. H01L 29/16; H01L 29/34; H01L 21/02; H01L 21/3065; H02M 7/04; H02M 1/08

(52) U.S. Cl. CPC H01L 29/1608; H01L 29/34; H01L 21/02529; H02P 27/06; H01L 21/3065; H02M 7/04; H02M 1/08; H01L 21/02378

(57) ABSTRACT

A silicon carbide epitaxial wafer includes a silicon carbide substrate and silicon carbide epitaxial layers formed on the silicon carbide substrate. Each of the silicon carbide epitaxial layers has a triangular defect. The silicon carbide epitaxial layer each have a step inside the triangular defect in the surface morphology of the triangular defect.

### BACKGROUND OF THE INVENTION

### Field of the Invention

The present invention relates to a silicon carbide epitaxial wafer.

### Description of the Background Art

Silicon carbide (SiC) has a larger band gap than silicon (Si), and has superior physical properties such as dielectric breakdown electric field strength, saturation electron velocity, and thermal conductivity as compared to silicon. Silicon carbide has excellent properties as a material for a semiconductor device. In particular, since a semiconductor device using silicon carbide can significantly reduce power loss and reduce the size of the semiconductor device, energy saving can be realized during power supply power conversion. Accordingly, silicon carbide has attracted attention as a semiconductor material useful for realizing a low-carbon society in terms of improving the performance of electric vehicles or enhancing the functions of solar cell systems, and the like.

In order to manufacture a semiconductor device using silicon carbide, first of all, a film whose impurity concentration is controlled with high accuracy is epitaxially grown on a silicon carbide substrate by a chemical vapor deposition method (CVD method) using a silicon carbide epitaxial growth apparatus. The film thus formed is referred to as an epitaxial layer. At this time, the silicon carbide substrate is heated to a high temperature of about 1,500° C. or higher. The epitaxial layer can be formed into an n-type layer by, for example, adding nitrogen to an epitaxial growth gas. A wafer having an epitaxial layer formed on a silicon carbide substrate is called a silicon carbide epitaxial wafer, and a device further having an element region formed in a silicon carbide epitaxial wafer is called a silicon carbide semiconductor device.

A silicon carbide semiconductor device is produced by performing various processes on a silicon carbide epitaxial wafer. If the silicon carbide epitaxial wafer has defects due to troubles during growth of the silicon carbide substrate and the silicon carbide epitaxial layer, a portion incapable of holding a high voltage locally appears in the silicon carbide semiconductor device, and a leak current is generated. Since a silicon carbide semiconductor device in which a leak current is generated is likely to be a defective product, an increase in the density of such portions incapable of holding high voltages reduces the non-defective product rate at the time of manufacturing the silicon carbide semiconductor device. Defects that reduce the non-defective product rate are primarily defects due to lack of crystallographic uniformity of the silicon carbide epitaxial wafer. For example, such defects are caused because the periodicity of the atomic arrangement in the crystal is locally imperfect along the crystal growth direction. As one of current leakage defects accompanied with such stacking defects, a carrot defect and a triangular defect caused by silicon carbide epitaxial growth are known.

Silicon carbide crystals include a plurality of crystal types (polytypes) that differ in the periodicity of the atomic arrangement along the c-axis, even though the crystals have the same crystal lattice with hexagonal close-packed structures and the same stoichiometric composition as a Si:C ratio of 1:1. The physical properties of the crystals are defined by their periodicities. At present, the type called the 4H type is attracting the most attention from the viewpoint of device application. In order to epitaxially grow the same crystal type, the surface of the silicon carbide substrate is set to a plane inclined from a certain plane orientation of the crystal, and is processed into a surface inclined, for example, by 8° or 4° in the <11-20> direction from the (0001) plane. It is known that a silicon carbide substrate has a threading screw dislocation (TSD) or basal plane dislocation (BPD) as a crystal defect. It has been found that a TSD is converted into a current leak defect such as a carrot defect or a triangular defect during silicon carbide epitaxial growth. Some of TSDs are converted into current leak defects, and most of the TSDs are directly taken over to the silicon carbide epitaxial layer. However, since many TSDs exist in the silicon carbide substrate, it is required to suppress the conversion from TSDs to current leak defects.

Japanese Patent Application Laid-Open No. 2018-6384 discloses a method of growing a silicon carbide epitaxial layer by forming a device operation layer to 5 μm or more and 10 μm or less, then forming a defect reduction layer upon reducing the C/Si ratio within the range of 0.1 or more and 0.3 or less, and again returning the C/Si ratio to the C/Si ratio at the time of the growth of the device operation layer and growing the device operation layer. The device operation layer is a layer, of the epitaxial layer, which excludes a buffer layer and operates as a device. Japanese Patent Application Laid-Open No. 2018-6384 discloses that this reduces defects such as triangular defects and carrot or comet defects caused in the middle of the device operation layer.

Generally, when the C/Si ratio is changed, the intake amount of nitrogen that is in competition with the carbon sites of silicon carbide changes. For this reason, when the C/Si ratio is changed in the middle of the device operation layer as in Japanese Patent Application Laid-Open No. 2018-6384, the intake amount of nitrogen atoms, which determines the carrier concentration, changes so that the carrier concentration becomes nonuniform inside the device operation layer. In addition, immediately after the C/Si ratio is changed, the intake of nitrogen atoms becomes unstable, which affects the electrical characteristics of the device and reduces the yield.

### SUMMARY

An object of the present invention is to reduce carrot defects and triangular defects caused in the middle of a device operation layer in a silicon carbide epitaxial wafer without changing a C/Si ratio in the middle of a device operation layer.

The silicon carbide epitaxial wafer according to the present invention includes a silicon carbide substrate and a silicon carbide epitaxial layer. The silicon carbide epitaxial layer is formed on the silicon carbide substrate. The silicon carbide epitaxial layer has a triangular defect and a step inside the triangular defect in the surface morphology of the triangular defect.

According to the present invention, in a silicon carbide epitaxial wafer, distortion in the silicon carbide epitaxial layer can be reduced, and carrot defects and triangular defects caused from the silicon carbide epitaxial layer can be reduced without changing the C/Si ratio in the middle of the device operation layer.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a silicon carbide epitaxial wafer according to a first preferred embodiment;

FIG. 2 is a sectional view showing a main part of a silicon carbide epitaxial growth apparatus;

FIG. 3 is a photograph of triangular defects present in the silicon carbide epitaxial wafer according to the first preferred embodiment observed with an optical surface defect evaluation apparatus;

FIG. 4 is a diagram showing results of comparing the numbers of carrot defects and triangular defects in the silicon carbide epitaxial wafer according to the first preferred embodiment and a silicon carbide epitaxial wafer according to a comparative example;

FIG. 5 is a diagram showing the etching time dependency of the number of carrot defects and the number of triangular defects of the silicon carbide epitaxial wafer according to the first preferred embodiment;

FIG. 6 is a sectional view showing a structure of a silicon carbide epitaxial wafer according to a second preferred embodiment; and

FIG. 7 is a block diagram showing a configuration of a power conversion system to which a power converter according to a third preferred embodiment is applied.

### DESCRIPTION OF THE PREFERRED EMBODIMENTS

### A. First Preferred Embodiment

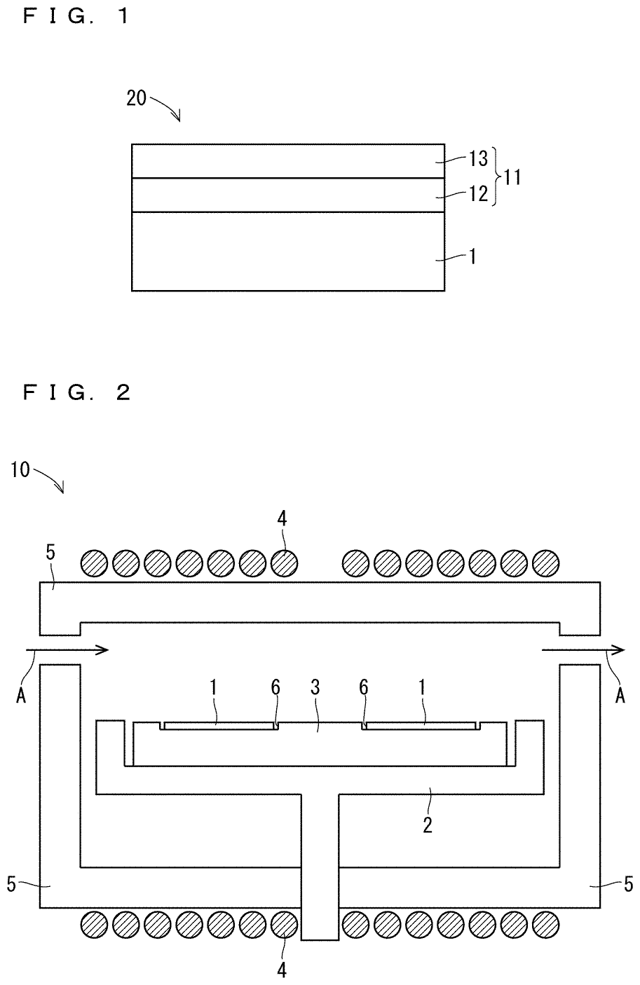

FIG. 1 is a sectional view showing a configuration of a silicon carbide epitaxial wafer 20 according a first preferred embodiment. The silicon carbide epitaxial wafer 20 includes a silicon carbide substrate 1 and a silicon carbide epitaxial layer 11 formed on the silicon carbide substrate 1. The silicon carbide substrate 1 is of an n-type and has low resistance. The main surface of the silicon carbide substrate 1 has an off angle in the <11-20> direction from the (0001) plane. The off angle is about 5° or less.

The silicon carbide epitaxial layer 11 includes a first silicon carbide epitaxial layer 12 formed on the silicon carbide substrate 1 and a second silicon carbide epitaxial layer 13 formed on the first silicon carbide epitaxial layer 12. The first silicon carbide epitaxial layer 12 and the second silicon carbide epitaxial layer 13 have the same conductivity type as that of the silicon carbide substrate 1, and are specifically of the n-type.

FIG. 2 is a sectional view showing a schematic configuration of a growth furnace 10, which is a main part of a silicon carbide epitaxial growth apparatus used for manufacturing the silicon carbide epitaxial wafer 20. The growth furnace 10 includes a turntable 2, a wafer holder 3, a susceptor 5, and an induction heating coil 4. The disc-shaped wafer holder 3 is placed on the turntable 2 and rotates at a constant speed together with the turntable 2. A plurality of wafer pockets 6 are formed on the surface of the wafer holder 3 by performing a counterboring process, and the silicon carbide substrates 1 are placed in the wafer pockets 6. The turntable 2 and the wafer holder 3 are arranged in the susceptor 5 and are induction-heated together with the susceptor 5.

A growth gas is supplied into the susceptor 5. An arrow A in FIG. 2 indicates the flow of the growth gas. As the growth gas, SiH₄ gas (silane gas) containing silicon atoms and C₃H₈ gas (propane gas) containing carbon atoms can be used. A carrier gas containing H₂ can be used. The growth temperature is, for example, 1,450° C. or more and 1,700° C. or less, and the growth pressure is, for example, 1×10³ Pa or more and 5×10⁴ Pa or less. If necessary, a nitrogen gas for n-type impurity doping may be supplied simultaneously with the growth gas, or an organometallic material containing Al, B, or Be for p-type impurity doping may be supplied. Further, HCl or dichlorosilane can be used to increase the growth rate.

A method for forming the silicon carbide epitaxial layer 11 on the silicon carbide substrate 1 using the growth furnace 10 will be described. First, the silicon carbide substrate 1 is placed in the wafer pocket 6 of the wafer holder 3 outside the susceptor 5. The wafer holder 3 on which the silicon carbide substrate 1 is placed is placed on the turntable 2 provided in the susceptor 5.

Next, the inside of the susceptor 5 is depressurized. Then, electric power is supplied to the induction heating coil 4 wound around the outer periphery of the susceptor 5. By supplying electric power to the induction heating coil 4, the susceptor 5 and the turntable 2 are induction-heated. When the susceptor 5 and the turntable 2 are induction-heated, the depressurized space in the susceptor 5 is also heated by radiant heat from the inner wall and the like of the susceptor 5.

The same material is used for the wafer holder 3, the turntable 2, and the susceptor 5. The silicon carbide substrate 1 is heated by radiant heat from the inner wall and the like of the susceptor 5 and conductive heat from the wafer holder 3. When the turntable 2 is U-shaped, the silicon carbide substrate 1 is also heated by radiant heat from a side portion of the turntable 2. When the silicon carbide substrate 1 reaches a desired temperature, a growth gas is supplied into the susceptor 5. In order to form an epitaxial layer on the silicon carbide substrate 1, it is necessary to decompose the growth gas or the like supplied into the susceptor 5 on the silicon carbide substrate 1, so that the silicon carbide substrate 1 is heated up to about 1,500° C.

Growth gases include SiH₄ gas, C₃H₈ gas, and H₂ gas. When it is necessary to adjust the electrical characteristics of the silicon carbide epitaxial layer 11 formed on the silicon carbide substrate 1, trimethylaluminum (TMA) gas as a p-type dopant or N₂ gas as an n-type dopant is supplied together with growth gas as needed. In this preferred embodiment, N₂ gas was supplied together with the growth gas. Since the susceptor 5 is structured to be evacuated simultaneously with the supply of a growth gas or the like, the susceptor 5 is always filled with the new growth gas or the like. Since the silicon carbide substrate 1 is heated to about 1,500° C. or higher, the growth gas supplied into the susceptor 5 is decomposed on the silicon carbide substrate 1, and an epitaxial layer can be formed on the silicon carbide substrate 1.

The same material is used for the wafer holder 3, the turntable 2, and the susceptor 5. In this preferred embodiment, graphite coated with silicon carbide is used as a material for the wafer holder 3, the turntable 2, and the susceptor 5. This is because when an epitaxial layer is formed on the silicon carbide substrate 1, the silicon carbide substrate 1 needs to be heated to about 1,500° C. or higher and must be able to withstand the heating.

If the wafer holder 3, the turntable 2, and the susceptor 5 are made of only graphite, there is a possibility that graphite generates dust during the formation of an epitaxial layer. If the epitaxial layer is formed with the fine particles generated from graphite being placed on the silicon carbide substrate 1, a crystal grows abnormally starting from the place where the fine particles are placed, and crystal defects occur in the epitaxial layer. On the other hand, when graphite coated with silicon carbide is used as a material for the wafer holder 3, the turntable 2, and the susceptor 5, the generation of dust from graphite is suppressed by the silicon carbide film. Also, diffusion of metal impurities from graphite is suppressed. It is preferable that the metal impurities do not diffuse because the metal impurities cause crystal defects in the epitaxial layer and affect the electrical characteristics of the semiconductor device. Therefore, it is preferable to use graphite coated with silicon carbide for the wafer holder 3, the turntable 2, and the susceptor 5. Alternatively, a silicon carbide material produced by a CVD method or a sintering method may be used. In addition to silicon carbide, TaC or CVD carbon coating may be used as a coating material. Next, H₂ gas as a carrier gas is flowed at a constant flow rate to adjust the pressure in the growth furnace 10 to 1×10³ Pa or more and 5×10⁴ Pa or less. Then, SiH₄ gas, C₃H₈ gas, and N₂ gas are supplied into the growth furnace 10 to form the first silicon carbide epitaxial layer 12 on the silicon carbide substrate 1. Before forming the first silicon carbide epitaxial layer 12, the silicon carbide substrate 1 may be heated at 1,500° C. or higher while flowing only H₂ gas, thereby removing silicon carbide particles attached to the surface of the silicon carbide substrate 1. This makes it possible to obtain a silicon carbide epitaxial wafer with few epitaxial defects.

After growing the first silicon carbide epitaxial layer 12 to a predetermined thickness, the surface of the first silicon carbide epitaxial layer 12 is etched. In this preferred embodiment, the supply of SiH₄ gas, C₃H₈ gas, and N₂ gas as growth gases is stopped, and the surface of the first silicon carbide epitaxial layer 12 is etched while only H₂ gas as a carrier gas is flowed. At this time, the flow rate of H₂ gas and the pressure during the etching process are the same as those during the growth of the first silicon carbide epitaxial layer 12. This maintains the continuity of the gas flow in the growth furnace 10 and hence can suppress the generation of dust due to the airflow fluctuation of the gas in the growth furnace 10. In this preferred embodiment, the supply of the growth gas is stopped and etching is performed with H₂ gas. However, etching may be performed while supplying the growth gas. In this case, epitaxial growth and etching are performed at the same time. However, it is only necessary to adjust the flow rates of SiH₄ gas, C₃H₈ gas, and N₂ gas as growth gases so as to make the etching become dominant over the growth.

The etching amount of the first silicon carbide epitaxial layer 12 can be adjusted by changing the flow rate, pressure, temperature, or the like of H₂ gas as a carrier gas. In this preferred embodiment, the etching amount of the first silicon carbide epitaxial layer 12 was set to about 50 nm. The etching amount is desirably 1 nm or more and 100 nm or less. If the etching amount is less than 1 nm, the distortion of the first silicon carbide epitaxial layer 12 may not be sufficiently removed, which is not preferable. On the other hand, if the etching amount exceeds 100 nm, it is not preferable from the viewpoint of productivity because the etching amount is sufficient as a distortion removal amount and the etching processing time is too long. However, since the distortion generated in the first silicon carbide epitaxial layer 12 may vary depending on the growth condition and thickness of the first silicon carbide epitaxial layer 12 or the crystal state of the silicon carbide substrate 1, the etching amount is not limited to the above range.

The ratio (C/Si ratio) of the number of C atoms contained in C₃H₈ gas and the number of Si atoms contained in SiH₄ gas may be the same as or different from the C/Si ratio of the first epitaxial layer.

The flow rate of the carrier gas (H₂) was set to be the same when forming the first silicon carbide epitaxial layer 12 and when etching the first silicon carbide epitaxial layer 12. If the flow rate fluctuates greatly, dust generation may occur due to airflow fluctuations. Therefore, it is preferable to keep the carrier gas flow rate constant from the viewpoint of yield. However, the flow rate of the carrier gas may be different when the first silicon carbide epitaxial layer 12 is formed and when the first silicon carbide epitaxial layer 12 is etched.

In this preferred embodiment, the distortion of the surface layer of the first silicon carbide epitaxial layer 12 is removed by etching with H₂ gas, but another method capable of removing the distortion of first silicon carbide epitaxial layer 12 may be used. For example, the surface of the first silicon carbide epitaxial layer 12 may be etched by a method such as chemical mechanical polishing (CMP), liquid phase etching, or vapor phase etching using a halogen-based gas.

Next, the second silicon carbide epitaxial layer 13 is formed by gradually increasing the flow rates of SiH₄ gas, C₃H₈ gas, and N₂ gas. Here, the flow rates of SiH₄ gas, C₃H₈ gas, and N₂ gas may be the same as or different from those when the first silicon carbide epitaxial layer 12 is formed.

As the silicon carbide epitaxial layer 11 becomes thicker, the distortion accumulated in the silicon carbide epitaxial layer 11 increases. When the thickness exceeds the critical film thickness, dislocations are introduced to alleviate the distortion. Consequently, carrot defects or triangular defects are generated. However, in this preferred embodiment, as described above, etching is performed when epitaxial growth is performed to a certain thickness, and epitaxial growth is performed again. This can reduce distortion in the silicon carbide epitaxial layer 11 and carrot defects and triangular defects caused from the silicon carbide epitaxial layer 11.

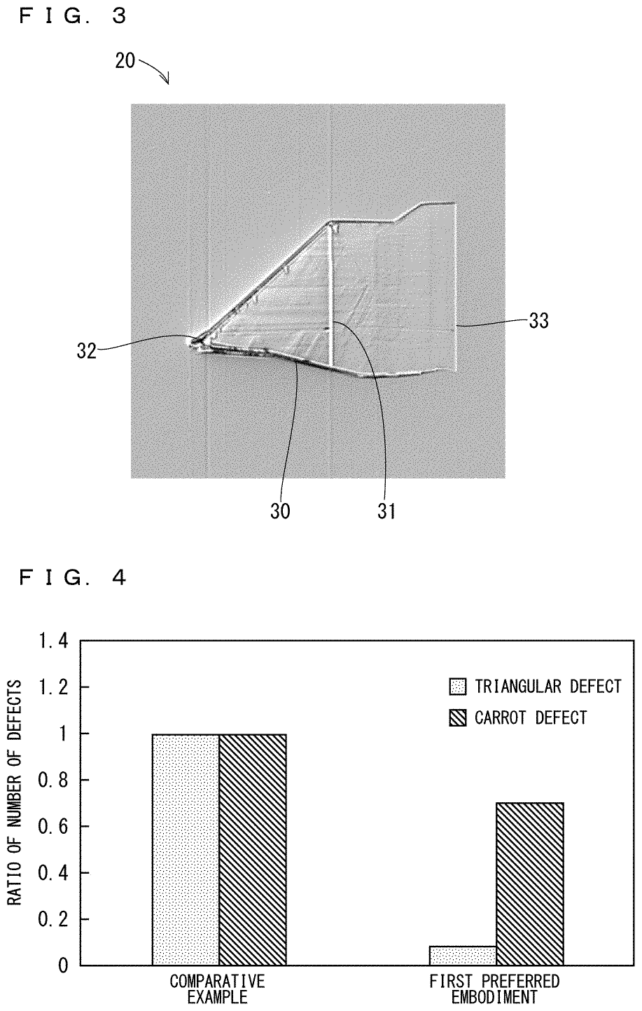

FIG. 3 shows an image obtained by observing a triangular defect contained in the silicon carbide epitaxial wafer 20 after the formation of the second silicon carbide epitaxial layer 13 with an optical surface defect evaluation apparatus. As can be seen from FIG. 3, a step 31 is formed inside a triangular defect 30. Referring to FIG. 3, a direction of the step flow of epitaxial growth is from the left to the right of the drawing surface. An apex 32 and a base 33 of the triangular defect 30 are aligned in the step flow direction.

The step 31 is produced as a result of etching during epitaxial growth. The direction of the edge of the step 31 is perpendicular to the step flow direction. In other words, the edge of the step 31 is parallel to the base 33 of the triangular defect 30. Further, the surface of the second silicon carbide epitaxial layer 13 on the left side of the step 31, that is, a portion before the step 31 along the step flow direction, is lower than the surface of the second silicon carbide epitaxial layer 13 on the right side of the step 31, that is, a portion after the step 31 along the step flow direction.

A silicon carbide epitaxial wafer obtained without performing the etching of the first silicon carbide epitaxial layer 12 and the formation of the second silicon carbide epitaxial layer 13 was prepared as a comparative example and compared with the silicon carbide epitaxial wafer 20 according to the first preferred embodiment. The thickness of the first silicon carbide epitaxial layer 12 in the silicon carbide epitaxial wafer of the comparative example is equal to the sum of the thickness of the first silicon carbide epitaxial layer 12 and the thickness of the second silicon carbide epitaxial layer 13 in the silicon carbide epitaxial wafer 20 according to the first preferred embodiment. In the silicon carbide epitaxial wafer of the comparative example, no step is formed inside the triangular defect in the surface morphology of the triangular defect. In addition, the growth apparatus used in the comparative example and the conditions for forming the first silicon carbide epitaxial layer 12 are the same as those in the first preferred embodiment.

FIG. 4 shows the results of evaluating the numbers of carrot defects and triangular defects using the optical surface defect evaluation apparatus with respect to the silicon carbide epitaxial wafer 20 according to the first preferred embodiment and the silicon carbide epitaxial wafer of the comparative example. In order to eliminate the influences of location dependency in the ingots, this evaluation was performed upon position matching in the respective ingots. It can be seen from FIG. 4 that the silicon carbide epitaxial wafer 20 according to the first preferred embodiment has significantly reduced both carrot defects and triangular defects as compared to the silicon carbide epitaxial wafer of the comparative example.

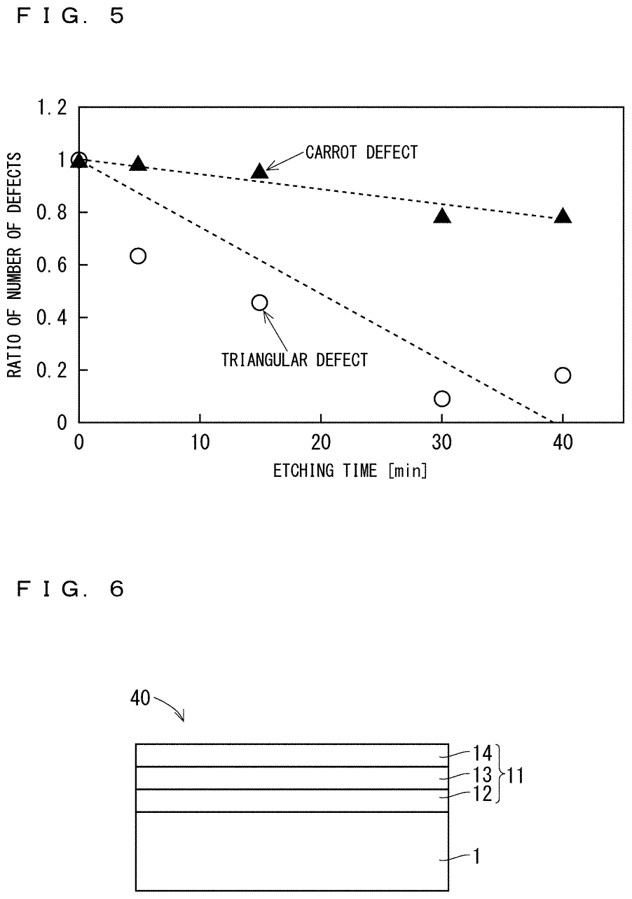

FIG. 5 shows the results of checking the etching time dependency of the number of carrot defects and the number of triangular defects in the silicon carbide epitaxial wafer 20 according to the first preferred embodiment. The inspection was carried out for up to an etching time of 40 min. It was confirmed that any defect tends to decrease as the etching time increases. However, since the surface roughness of the silicon carbide epitaxial layer 11 increases as the etching time increases, the etching time is preferably 5 min or longer and 30 min or shorter.

### B. Second Preferred Embodiment

In the first preferred embodiment, the surface was etched once in the process of forming the silicon carbide epitaxial layer 11. According to the study by the present inventors, it is preferable to determine the number of etchings according to the thickness of the silicon carbide epitaxial layer 11. More specifically, it is preferable to perform etching every time the silicon carbide epitaxial layer 11 is formed to 2 μm or more and 20 μm or less, more preferably 5 μm or more and 15 μm or less. If the thickness of the silicon carbide epitaxial layer 11 that grows before etching is larger than the above, dislocations are introduced to alleviate distortion of the silicon carbide epitaxial layer 11 and cause the occurrence of carrot defects and triangular defects, which is not preferable. Further, if the thickness of the silicon carbide epitaxial layer 11 grown before etching is smaller than the above, etching becomes frequent, which is not preferable because productivity decreases.

In the second preferred embodiment, a silicon carbide epitaxial wafer produced through two etchings will be described. FIG. 6 is a sectional view of a silicon carbide epitaxial wafer 40 according to the second preferred embodiment. The silicon carbide epitaxial wafer 40 includes a silicon carbide substrate 1 and a silicon carbide epitaxial layer 11 formed on the silicon carbide substrate 1. The silicon carbide epitaxial layer 11 includes a first silicon carbide epitaxial layer 12, a second silicon carbide epitaxial layer 13 formed on the first silicon carbide epitaxial layer 12, and a third silicon carbide epitaxial layer 14 formed on the second silicon carbide epitaxial layer 13. The silicon carbide epitaxial wafer 40 is different from the silicon carbide epitaxial wafer 20 according to the first preferred embodiment in that the silicon carbide epitaxial wafer 40 includes the third silicon carbide epitaxial layer 14.

The silicon carbide epitaxial wafer 20 according to the first preferred embodiment is obtained by forming the first silicon carbide epitaxial layer 12 on the silicon carbide substrate 1, then performing an etching process once, and then forming the second silicon carbide epitaxial layer 13. In contrast, the silicon carbide epitaxial wafer 40 is obtained by repeating an etching process and epitaxial growth twice after the formation of the first silicon carbide epitaxial layer 12. That is, as in the first preferred embodiment, the silicon carbide epitaxial wafer 40 is obtained by forming the second silicon carbide epitaxial layer 13, then performing an etching process, and then forming the third silicon carbide epitaxial layer 14.

The growth apparatus used for epitaxial growth and the growth conditions for the silicon carbide epitaxial wafer 40 are the same as those for the silicon carbide epitaxial wafer 20 according to the first preferred embodiment. Note that the total thickness of the silicon carbide epitaxial layer 11 in the silicon carbide epitaxial wafers 20 and 40 was set to the same thickness, 30 μm. The total etching time was also set to the same time, 30 min.

In the first preferred embodiment, etching was performed only once when the thickness of the silicon carbide epitaxial layer 11 from the surface of the silicon carbide substrate 1 reached 15 μm, whereas in the second preferred embodiment, etching was performed at each of the timings when the thickness of the silicon carbide epitaxial layer 11 from the surface of the silicon carbide substrate 1 reached 10 μm and 20 μm. As a result of taking out the silicon carbide epitaxial wafer 40 from the growth apparatus and evaluating the numbers of carrot defects and triangular defects using an optical surface defect evaluation apparatus, the numbers of carrot defects and triangular defects became almost the same as those in the silicon carbide epitaxial wafer 20 according to the first preferred embodiment.

According to the above description, the etching of the silicon carbide epitaxial layer 11 and the subsequent formation of the silicon carbide epitaxial layer 11 are repeated twice, but the etching and the formation may be repeated for an arbitrary number of three times or more. When the etching of the silicon carbide epitaxial layer 11 and the subsequent formation of the silicon carbide epitaxial layer 11 are repeated a plurality of times, steps 31 corresponding in number to the number of etchings are formed inside a triangular defect 30 in the surface morphology of the triangular defect 30 in the silicon carbide epitaxial layer 11. From the viewpoint of productivity, it is desirable to perform etching every time the silicon carbide epitaxial layer 11 is formed to 15 μm. However, if the growth apparatus or the epitaxial growth conditions differ, the distortion of the silicon carbide epitaxial layer 11 may also differ. Therefore, the required number of etchings is not limited to the number described in this preferred embodiment.

The method for manufacturing the silicon carbide epitaxial wafers 20 and 40 described in the first and second preferred embodiments can reduce carrot defects or triangular defects originating from crystal defects of the silicon carbide substrate 1. However, the silicon carbide substrate 1 contains many crystal defects such as threading edge dislocation (TED), threading screw dislocation (TSD), or basal plane dislocation (BPD), from which carrot defects or triangular defects originate. Accordingly, it is stochastically difficult to stably eliminate triangular defects. In addition, there are a large number of dust particles in the growth furnace 10, and triangular defects are formed originating from dust particles that have fallen on the silicon carbide substrate 1. This makes it difficult to stably eliminate triangular defects originating from dust particles. For these reasons, at present, it is difficult to stably produce a silicon carbide epitaxial wafer having no triangular defect. Therefore, assuming that the silicon carbide epitaxial wafer 20 according to the first preferred embodiment and the silicon carbide epitaxial wafer 40 according to the second preferred embodiment have triangular defects, each silicon carbide epitaxial wafer is characterized in that a step is formed inside a triangular defect in the surface morphology of the triangular defect.

As described above, the silicon carbide epitaxial wafers 20 and 40 of the first and second preferred embodiments each include the silicon carbide substrate 1 and the silicon carbide epitaxial layer 11 formed on the silicon carbide substrate 1. The silicon carbide epitaxial layer 11 has the triangular defect 30 and the step 31 inside the triangular defect 30 in the surface morphology of the triangular defect 30. The fact that the silicon carbide epitaxial layer 11 has the step 31 inside the triangular defect 30 in the surface morphology of the triangular defect 30 means that etching was performed during the formation of the silicon carbide epitaxial layer 11. This etching alleviates distortion in silicon carbide epitaxial layer 11 and hence reduces carrot defects or triangular defects generated in the silicon carbide epitaxial layer 11.

Further, in silicon carbide epitaxial wafers 20 and 40 according to the first and second preferred embodiments, the apex 32 and the base 33 of the triangular defect 30 are aligned in the step flow direction when the silicon carbide epitaxial layer 11 is formed, and the edge of the step 31 is parallel to the base 33. The fact that the edge of the step 31 is parallel to the base 33 indicates that etching was performed during the epitaxial growth, and that the step 31 was not caused by polishing scratches or the like existing on the silicon carbide substrate 1 in advance. This etching alleviates distortion in the silicon carbide epitaxial layer 11 and hence reduces carrot defects or triangular defects generated in the silicon carbide epitaxial layer 11.

Further, in each of the silicon carbide epitaxial wafers 20 and 40 according to the first and second preferred embodiments, a portion before the step of the surface of the silicon carbide epitaxial layer 11 along the step flow direction is lower than a portion after the step when the silicon carbide epitaxial layer 11 is formed. This means that the surface layer of the silicon carbide epitaxial layer 11 including distortion was removed during the epitaxial growth. This reduces carrot defects or triangular defects generated in the silicon carbide epitaxial layer 11.

The method for manufacturing each of the silicon carbide epitaxial wafers 20 and 40 according to the first and second preferred embodiments includes preparing the silicon carbide substrate 1, forming the first silicon carbide epitaxial layer 12 on the silicon carbide substrate 1 to a thickness of 5 μm or more and 15 μm or less, etching the first silicon carbide epitaxial layer 12 to a thickness of 5 nm or more and 100 nm or less, and after the etching, forming the second silicon carbide epitaxial layer 13 on the first silicon carbide epitaxial layer 12. As described above, etching during the epitaxial growth alleviates distortion in the first silicon carbide epitaxial layer 12, and hence can reduce carrot defects and triangular defects caused by the distortion.

### C. Third Preferred Embodiment

In the third preferred embodiment, the semiconductor devices formed on the silicon carbide epitaxial wafers 20 and 40 according to the first and second preferred embodiments are each applied to a power converter. Although the semiconductor device is not limited to a specific power converter, an example of application to a three-phase inverter will be described below as the third preferred embodiment.

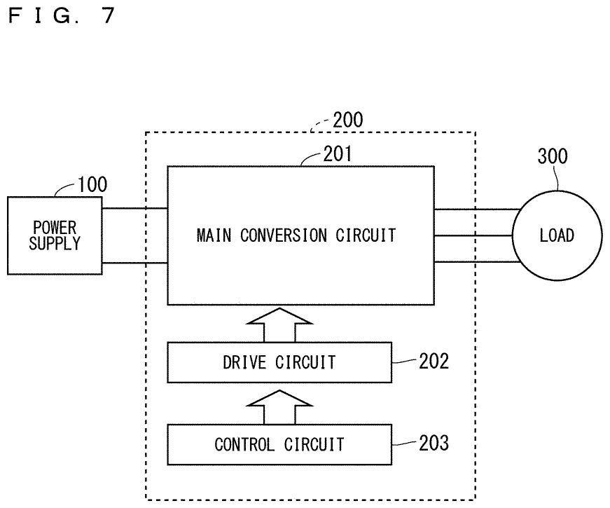

FIG. 7 is a block diagram showing a configuration of a power conversion system to which the power converter according to the third preferred embodiment is applied.

The power conversion system shown in FIG. 7 includes a power supply 100, a power converter 200, and a load 300. The power supply 100 is a DC power supply and supplies DC power to the power converter 200. The power supply 100 can be formed from various components, for example, a DC system, a solar cell, a storage battery, or a rectifier circuit or AC/DC converter connected to an AC system. Alternatively, the power supply 100 may be formed from a DC/DC converter that converts DC power output from a DC system into predetermined power.

The power converter 200 is a three-phase inverter connected between the power supply 100 and the load 300, converts the DC power supplied from the power supply 100 into AC power, and supplies the AC power to the load 300. As shown in FIG. 7, the power converter 200 includes a main conversion circuit 201 that converts DC power into AC power and outputs the AC power, and a drive circuit 202 that outputs a drive signal that drives each switching element of the main conversion circuit 201, and a control circuit 203 that outputs to the drive circuit 202 a control signal for controlling the drive circuit 202.

The load 300 is a three-phase electric motor driven by AC power supplied from the power converter 200. Note that the load 300 is not limited to a specific application, and is an electric motor mounted on various electric devices. For example, the load 300 is used as an electric motor for a hybrid vehicle or an electric vehicle, a railroad vehicle, an elevator, or an air conditioner.

The details of the power converter 200 will be described below. The main conversion circuit 201 includes a switching element and a reflux diode (not shown). When the switching element is switched on, the main conversion circuit 201 converts DC power supplied from the power supply 100 into AC power and supplies the AC power to the load 300. Although there are various specific circuit configurations of the main conversion circuit 201, the main conversion circuit 201 according to this preferred embodiment is a two-level three-phase full bridge circuit, and includes six switching elements and six reflux diodes antiparallel-connected to the respective switching elements. The semiconductor device formed on one of the silicon carbide epitaxial wafers 20 and 40 according to the first and second preferred embodiments described above is applied to at least one of each switching element and each reflux diode of the main conversion circuit 201. Six switching elements are connected in series for every two switching elements to constitute upper and lower arms, and each of the upper and lower arms constitutes each phase (U-phase, V-phase, or W-phase) of the full bridge circuit. The output terminals of the upper and lower arms, that is, the three output terminals of the main conversion circuit 201 are connected to the load 300.

The drive circuit 202 generates a drive signal for driving the switching element of the main conversion circuit 201 and supplies the drive signal to the control electrode of the switching element of the main conversion circuit 201. More specifically, in accordance with a control signal from a control circuit 203 (to be described later), a drive signal for turning on the switching element and a drive signal for turning off the switching element are output to the control electrode of each switching element. When the switching element is maintained ON, a drive signal is a voltage signal (ON signal) that is equal to or higher than the threshold voltage of the switching element. When the switching element is maintained OFF, a drive signal is a voltage signal (OFF signal) that is equal to or lower than the threshold voltage of the switching element.

The control circuit 203 controls the switching element of the main conversion circuit 201 so as to supply desired power to the load 300. More specifically, based on the power to be supplied to the load 300, the time (on time) during which each switching element of the main conversion circuit 201 is to be turned on is calculated. For example, the main conversion circuit 201 can be controlled by PWM control that modulates the on time of the switching element in accordance with the voltage to be output. A control command (control signal) is then output to the drive circuit 202 so as to output an ON signal to the switching element that should be turned on and output an OFF signal to the switching element that should be turned off at each time point. In accordance with this control signal, the drive circuit 202 outputs an ON signal or OFF signal as a drive signal to the control electrode of each switching element.

In the power converter according to this preferred embodiment, the yield is improved because the semiconductor device formed in any one of the silicon carbide epitaxial wafers 20 and 40 according to the first and second preferred embodiments is applied as the switching element of the main conversion circuit 201.

In this preferred embodiment, the example in which the semiconductor device formed on each of the silicon carbide epitaxial wafers 20 and 40 according to the first and second preferred embodiments is applied to the two-level three-phase inverter has been described. This semiconductor device can be applied to various types of power converters. In this preferred embodiment, the two-level power converter has been exemplified. However, a three-level or multi-level power converter may be used. When power is supplied to a single-phase load, the semiconductor device formed on each of the silicon carbide epitaxial wafers 20 and 40 according to the first and second preferred embodiments may be applied to a single-phase inverter. In addition, when supplying power to a DC load or the like, it is possible to apply the semiconductor device formed on each of the silicon carbide epitaxial wafers 20 and 40 according to the first and second preferred embodiments to a DC/DC converter or AC/DC converter.

The power converter to which the semiconductor device formed on each of the silicon carbide epitaxial wafers 20 and 40 of the first and second preferred embodiments is applied is not limited to the case where the load described above is an electric motor. For example, this power converter can be used as a power supply device for an electric discharge machine, a laser processing machine, an induction heating cooker, or a non-contact power feeding system. In addition, the power converter can be used as a power conditioner for a solar power generation system or a power storage system.

Note that in the present invention, the respective preferred embodiments can be freely combined and can be modified and omitted as needed within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A silicon carbide epitaxial wafer comprising:
a silicon carbide substrate; and
a silicon carbide epitaxial layer formed on the silicon carbide substrate,
wherein the silicon carbide epitaxial layer has a triangular defect and a step inside the triangular defect in a surface morphology of the triangular defect.

2. The silicon carbide epitaxial wafer according to claim 1, wherein
an apex and a base of the triangular defect are aligned in a step flow direction during formation of the silicon carbide epitaxial layer, and
an edge of the step is parallel to the base.

3. The silicon carbide epitaxial wafer according to claim 1, wherein a portion before the step of a surface of the silicon carbide epitaxial layer along the step flow direction is lower than a portion after the step.

4. The silicon carbide epitaxial wafer according to claim 2, wherein a portion before the step of a surface of the silicon carbide epitaxial layer along the step flow direction is lower than a portion after the step.

5. A method for manufacturing a silicon carbide epitaxial wafer, the method comprising:
preparing a silicon carbide substrate;
forming a first silicon carbide epitaxial layer on the silicon carbide substrate to a thickness of 5 μm or more and 15 μm or less;
etching the first silicon carbide epitaxial layer to a thickness of 5 nm or more and 100 nm or less; and
after the etching, forming a second silicon carbide epitaxial layer on the first silicon carbide epitaxial layer.

6. A power converter comprising:
a main conversion circuit that has a semiconductor device formed on the silicon carbide epitaxial wafer according to claim 1 and converts and outputs input power;
a drive circuit that outputs to the semiconductor device a drive signal for driving the semiconductor device; and
a control circuit that outputs to the drive circuit a control signal for controlling the drive circuit.
